(19) United States
(12) Patent Application Publication
(10) Pub. No.: US 2018/0019281 A1
(43) Pub. Date: Jan. 18, 2018

(54) VARIABLE RESISTANCE MEMORY DEVICES AND METHODS OF FABRICATING THE SAME

(71) Applicant: Samsung Electronics Co., Ltd., Suwon-si (KR)

(72) Inventors: Ja bin LEE, Hwaseong-si (KR); Jeonghee Park, Hwaseong-si (KR); Dongho Ahn, Hwaseong-si (KR); Zhe Wu, Suwon-si (KR); Heeju Shin, Seoul (KR); Jinwoo Lee, Seoul (KR)

(73) Assignee: Samsung Electronics Co., Ltd., Suwon-si (KR)

(21) Appl. No.: 15/454,064

(22) Filed: Mar. 9, 2017

(30) Foreign Application Priority Data
Jul. 15, 2016 (KR) 10-2016-0089975

(51) Int. Cl. H01L 27/24; H01L 45/00

(52) U.S. Cl. CPC H01L 27/2427; H01L 45/1625; H01L 45/147; H01L 45/146; H01L 45/06; H01L 45/143; H01L 45/1233; H01L 45/144

(57) ABSTRACT

A variable resistance memory device may include separate memory cells between separate vertical intersections of first conductive lines extending in a first direction and second conductive lines extending in a second direction intersecting the first direction. A memory cell may include a switching element and a variable resistance structure coupled in series between a first conductive line and a second conductive line. The switching element may include at least one insulative impurity and a chalcogenide material. The variable resistance structure may reversibly switch phases, between a crystalline state and an amorphous state, at a first phase transition temperature, and the switching element may reversibly switch phases, between a crystalline state and an amorphous state, at a second phase transition temperature, where the second phase transition temperature is greater than the first phase transition temperature.

### CROSS-REFERENCE TO RELATED APPLICATIONS

This U.S. non-provisional patent application claims priority under 35 U.S.C. §119 of Korean Patent Application 10-2016-0089975 filed on Jul. 15, 2016, the entire contents of which are hereby incorporated by reference.

### BACKGROUND

The present inventive concepts relate to memory devices and, more particularly, to variable resistance memory devices and methods of fabricating the same.

Semiconductor devices can include memory devices and logic devices. Memory devices may store data. In general, semiconductor memory devices can be broadly classified as volatile memory devices and nonvolatile memory devices. A volatile memory device, for example, DRAM (Dynamic Random Access Memory) and SRAM (Static Random Access Memory), is a memory device which loses stored data when its power supply is interrupted. A nonvolatile memory device, for example, PROM (Programmable ROM), EPROM (Erasable PROM), EEPROM (Electrically EPROM) and Flash memory device, is a memory device which does not lose stored data even when its power supply is interrupted.

Next generation semiconductor memory devices, for example, MRAM (Magnetic Random Access Memory) and PRAM (Phase Change Random Access Memory) devices, are recently being developed to meet the trend of high performance and low power consumption of the semiconductor memory device. The next generation semiconductor memory devices include a material whose resistance changes depending on current or voltage supply and whose resistance is maintained even the current or voltage supply is interrupted.

### SUMMARY

Some example embodiments of the present inventive concepts provide variable resistance memory devices having enhanced reliability and/or methods of fabricating the same.

According to some example embodiments of the present inventive concepts, a variable resistance memory device may include: a plurality of first conductive lines extending in a first direction; a plurality of second conductive lines extending in a second direction that intersects the first direction; and a plurality of memory cells, the memory cells at separate intersections between the first conductive lines and the second conductive lines, respectively. Each memory cell may include a switching element and a variable resistance structure coupled in series between the at least one first conductive line and at least one second conductive line, the switching element including at least one insulative impurity and a chalcogenide material.

According to some example embodiments of the present inventive concepts, a method may include: forming a first conductive line extending on a substrate, the first conductive line extending in a first direction; forming a memory cell on the first conductive line, forming the memory cell including forming a switching element and a variable resistance structure coupled in series, the switching element including at least one insulative impurity and a chalcogenide material; and forming a second conductive line on the memory cell and extending in a second direction that intersects the first direction, such that the memory cell is electrically coupled to both the first conductive line and the second conductive line.

According to some example embodiments, a device may include: a memory cell configured to be electrically coupled to separate conductive lines at opposite ends. The memory cell may include: a variable resistance structure configured to reversibly switch phases, between a crystalline state and an amorphous state, at a first phase transition temperature, and a switching element configured to reversibly switch phases, between a crystalline state and an amorphous state, at a second phase transition temperature. The second phase transition temperature may be greater than the first phase transition temperature.

According to some example embodiments, a device may include: a memory cell configured to be electrically coupled to separate conductive lines at opposite ends. The memory cell may include: a switching element including at least one insulative impurity and a chalcogenide material, and a variable resistance structure coupled to the switching element, such that the switching element and the variable resistance structure are coupled in series between the opposite ends of the memory cell.

Details of some example embodiments are included in the description and drawings.

### BRIEF DESCRIPTION OF THE DRAWINGS

FIG. 1 is a schematic diagram illustrating a variable resistance memory device according to some example embodiments of the present inventive concepts.

FIG. 2 is a perspective view roughly illustrating a variable resistance memory device according to some example embodiments of the present inventive concepts.

FIG. 3 is a plan view illustrating a variable resistance memory device according to some example embodiments of the present inventive concepts.

FIG. 4A and FIG. 4B are cross-sectional views taken along lines IVA-IVA′ and IVB-IVB′ of FIG. 3, respectively.

FIG. 5A and FIG. 5B are schematic diagram illustrating a switching element according to some example embodiments of the present inventive concepts.

FIG. 6A is a schematic diagram illustrating a current flow in a switching element without insulative impurities.

FIG. 6B and FIG. 6C are schematic diagrams illustrating a current flow in a switching element according to some example embodiments of the present inventive concepts.

FIG. 7A, FIG. 8A, FIG. 9A, and FIG. 10A are cross-sectional views corresponding to line IVA-IVA′ of FIG. 3 for explaining a method of fabricating a variable resistance memory device according to some example embodiments of the present inventive concepts.

FIG. 7B, FIG. 8B, FIG. 9B, and FIG. 10B are cross-sectional views corresponding to line IVB-IVB′ of FIG. 3 for explaining a method of fabricating a variable resistance memory device according to some example embodiments of the present inventive concepts.

FIG. 11 shows a method of fabricating a switching element according to some example embodiments of the present inventive concepts.

FIG. 12A, FIG. 12B, and FIG. 12C show a method of fabricating a switching element according to some example embodiments of the present inventive concepts.

### DETAILED DESCRIPTION OF EMBODIMENTS

Example embodiments of the present inventive concepts are described herein with reference to accompanying drawings. The same reference numerals or the same reference designators may denote the same elements throughout the specification.

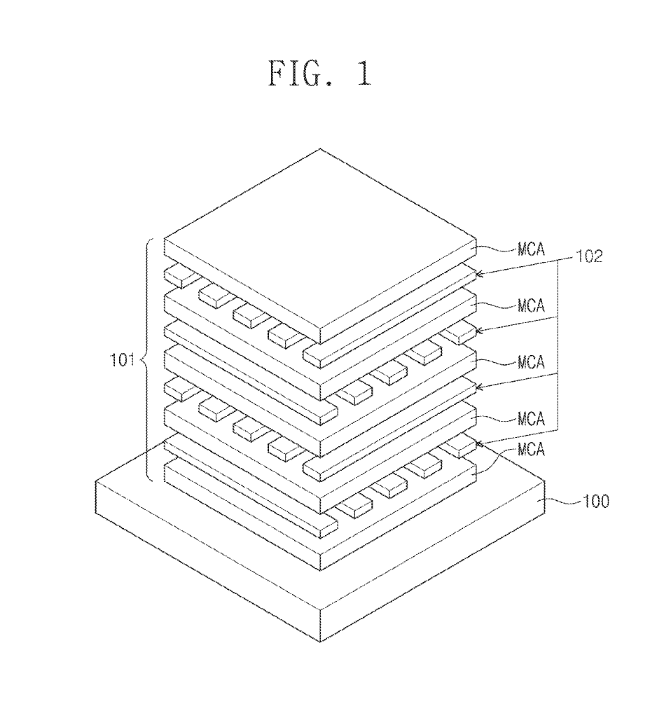

FIG. 1 is a schematic diagram illustrating a variable resistance memory device according to some example embodiments of the present inventive concepts.

Referring to FIG. 1, a variable resistance memory device may include a plurality 101 of memory cell stacks MCA sequentially stacked on a substrate 100. Each of the memory cell stacks MCA may include a plurality of memory cells arranged two-dimensionally. The variable resistance memory device may include a plurality of conductive lines 102 that are disposed between the memory cell stacks MCA and at least partially configure the memory cells included therein to perform writing, reading, and/or erasing operations. FIG. 1 shows five memory cell stacks MCA, but the present inventive concepts are not limited thereto.

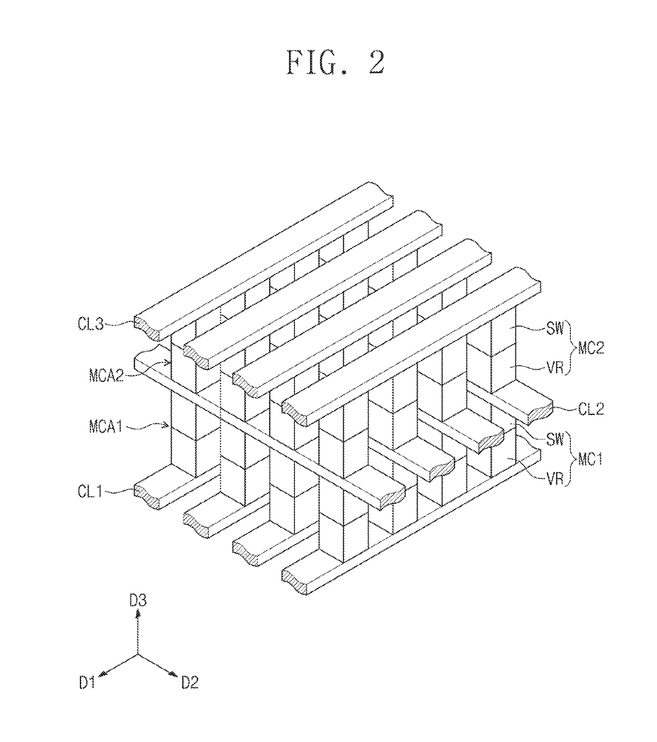

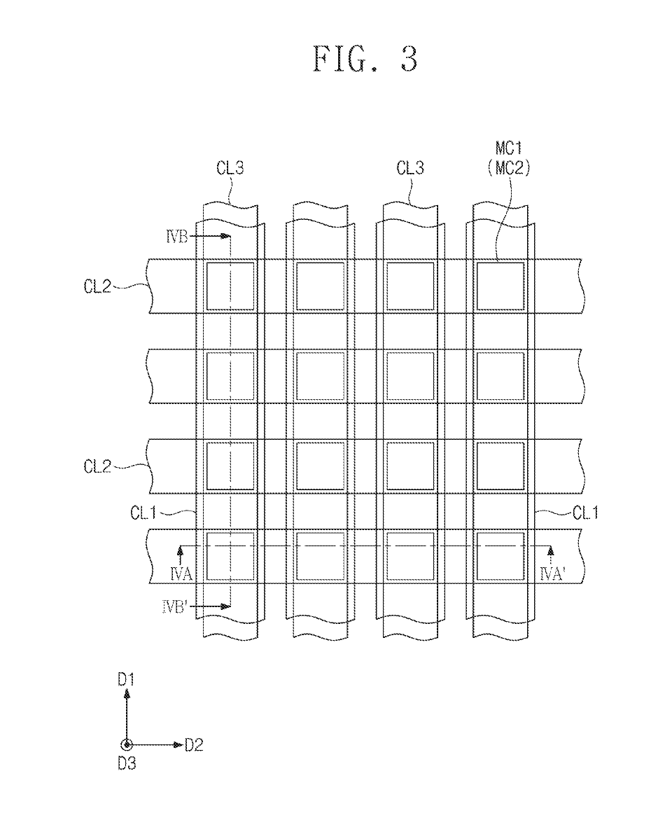

FIG. 2 is a perspective view roughly illustrating a variable resistance memory device according to some example embodiments of the present inventive concepts. In the example embodiments illustrated in FIG. 2, two memory cell stacks MCA1 and MCA2 are adjacent to each other, but the present inventive concepts are not limited thereto.

Referring to FIG. 2, first conductive lines CL1 extending in a first direction D1, second conductive lines CL2 extending in a second direction D2 intersects the first direction D1, and third conductive lines CL3 extending in the first direction D1 may be provided. The first to third conductive lines CL1 to CL3 may be provided sequentially and spaced apart from each other along a third direction D3 perpendicular or substantially perpendicular (e.g., perpendicular within manufacturing tolerances and/or material tolerances) to the first and second directions D1 and D2.

A first memory cell stack MCA1 may be provided between the first conductive lines CL1 and the second conductive lines CL2, and a second memory cell stack MCA2 may be provided between the second conductive line CL2 and the third conductive lines CL3. The first memory cell stack MCA1 may include first memory cells MC1 provided at intersections between the first conductive lines CL1 and the second conductive lines CL2, such that the first memory cells MC1 vertically overlap separate sets of first and second conductive lines CL1 and CL2, respectively. The first memory cells MC1 may be two-dimensionally arranged in row and column fashion. Likewise, the second memory cell stack MCA2 may include second memory cells MC2 provided at intersections between the second conductive lines CL2 and the third conductive lines CL3, such that the second memory cells MC2 vertically overlap separate sets of second and third conductive lines CL2 and CL3, respectively. The second memory cells MC2 may be two-dimensionally arranged in row and column fashion. Each memory cell may be coupled to separate conductive lines at opposite ends of the respective memory cell.

Each of the memory cells MC1 and MC2 may include a variable resistance structure VR and a switching element SW. The variable resistance structure VR and the switching element SW included in each of the memory cells MC1 and MC2 may be coupled in series between corresponding (i.e., coupled thereto) conductive lines CL1, CL2 and CL3 vertically overlapped by the memory cells MC1 and MC2, respectively. For example, the variable resistance structure VR and the switching element SW included in a first memory cell MC1 may be coupled in series between a pair of first and second conductive lines CL1 and CL2 that are coupled to opposite ends of the corresponding first memory cell MC1, and the variable resistance structure VR and the switching element SW included in a second memory cell MC2 may be coupled in series between a pair of second and third conductive lines CL2 and CL3 that are coupled to opposite ends of the corresponding second memory cell MC2. FIG. 2 shows that the switching element SW in each given second memory cell MC2 is provided between the variable resistance VR and a second conductive line CL2, but the present inventive concepts are not limited thereto. For example, the variable resistance structure VR in a given second memory cell MC2 may be provided between the switching element SW thereof and a second conductive line CL2.

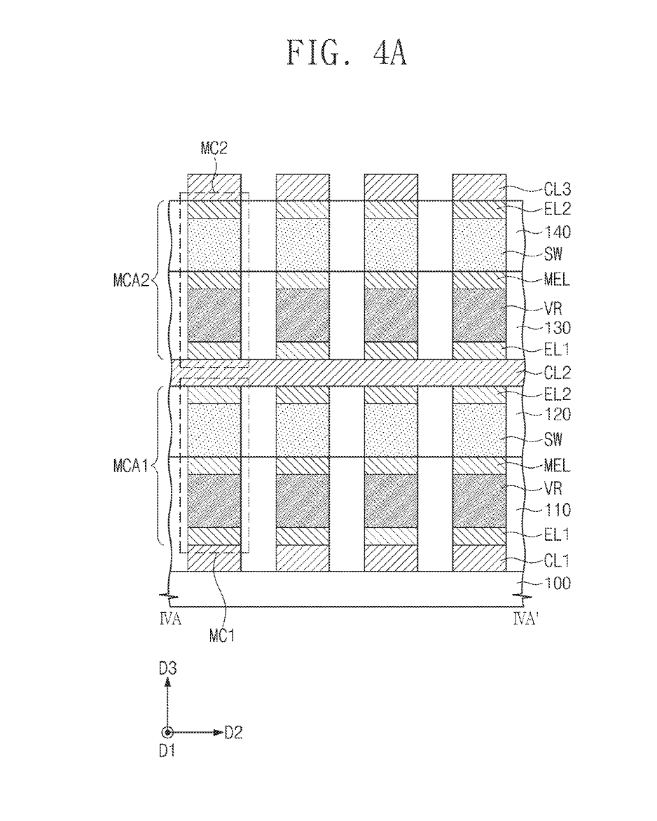

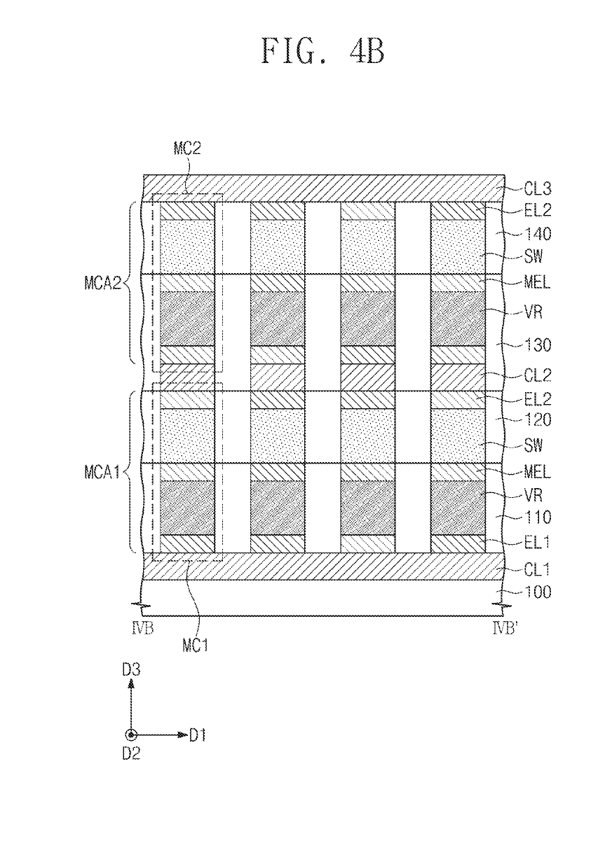

FIG. 3 is a plan view illustrating a variable resistance memory device according to some example embodiments of the present inventive concepts. FIGS. 4A and 4B are cross-sectional views taken along lines IVA-IVA′ and IVB-IVB′ of FIG. 3, respectively.

Referring to FIGS. 3, 4A and 4B, first conductive lines CL1, second conductive lines CL2, and third conductive lines CL3 may be sequentially provided on a substrate 100. The first conductive lines CL1 may extend in a first direction D1 parallel or substantially parallel (e.g., parallel within manufacturing tolerances and/or material tolerances) to a top surface of the substrate 100 and may be spaced apart from each other in a second direction D2 intersecting the first direction D1 and being substantially parallel to the top surface of the substrate 100. The second conductive lines CL2 may extend in the second direction D2 and may be spaced apart from each other in the first direction D1. The third conductive lines CL3 may extend in the first direction D1 and may be spaced apart from each other in the second direction D2. The first to third conductive lines CL1 to CL3 may be spaced apart from each other in a third direction D3 perpendicular to the top surface of the substrate 100. Each of the first to third conductive lines CL1 to CL3 may include metal (e.g., copper, tungsten, or aluminum) and/or metal nitride (e.g., tantalum nitride, titanium nitride, or tungsten nitride).

A first memory cell stack MCA1 may be provided between the first conductive lines CL1 and the second conductive lines CL2, and a second memory cell stack MCA2 may be provided between the second conductive line CL2 and the third conductive lines CL3. The first and second memory cell stacks MCA1 and MCA2 may correspond to the memory cell stacks discussed with reference to FIGS. 1 and 2. Although only two memory cell stacks MCA1 and MCA2 are illustrated in FIGS. 3 and 4A-4B, more than two memory cell stacks may be provided on a substrate. In the example embodiments illustrated in FIG. 3 and FIGS. 4A-4B, additional memory cell stacks similar to the first and second memory cell stacks MCA1 and MCA2 and additional conductive lines similar to the second and third conductive lines CL2 and CL3 may be provided on the substrate 100.

The first memory cell stack MCA1 may include first memory cells MC1 provided at intersections between the first conductive lines CL1 and the second conductive lines CL2, such that the first memory cell stack MCA1 includes first memory cells MC1 that each vertically overlap separate sets of first conductive lines CL1 and second conductive lines CL2, respectively. The second memory cell stack MCA2 may include second memory cells MC2 provided at intersections between the second conductive lines CL2 and the third conductive lines CL3, such that the second memory cell stack MCA2 includes second memory cells MC2 that each vertically overlap separate sets of second conductive lines CL2 and third conductive lines CL3, respectively.

Each of the memory cells MC1 and MC2 may include a variable resistance structure VR and a switching element SW that are coupled in series between a pair of conductive lines CL1 and CL2 (or CL2 and CL3) coupled to corresponding, opposite ends of each of the memory cells MC1 and MC2.

The variable resistance structures VR included in the same memory cell stack MCA1 or MCA2 may be disposed at intersections between conductive lines CL1, CL2 and CL3 as shown in FIGS. 4A and 4B, thereby providing a two-dimensional arrangement. However, the present inventive concepts are not limited thereto. For example, each of the variable resistance structures VR included in the same memory cell stack MCA1 or MCA2 may have a line shape extending along either the first direction D1 or the second direction D2. In this case, a single variable resistance structure VR may be shared between a plurality of memory cells MC1 or MC2 that are arranged along either the first direction D1 or the second direction D2.

The switching elements SW included in the same memory cell stack MCA1 or MCA2 may be disposed at intersections between conductive lines CL1, CL2 and CL3 as shown in FIGS. 4A and 4B, thereby providing a two-dimensional arrangement. However, the present inventive concepts are not limited thereto. For example, each of the switching elements SW included in the same memory cell stack MCA1 or MCA2 may have a line shape extending along either the first direction D1 or the second direction D2. In this case, a single switching element SW may be shared between a plurality of memory cells MC1 or MC2 that are arranged along either the first direction D1 or the second direction D2.

In some example embodiments, as shown in FIGS. 4A and 4B, the variable resistance structure VR may be provided between the switching element SW included in the same memory cell MC1 or MC2 and the substrate 100. In some example embodiments, the switching element SW may be provided between the variable resistance structure VR included in the same memory cell MC1 or MC2 and the substrate 100. For brevity of the description, it will be hereinafter described that the variable resistance structure VR may be provided between the substrate 100 and the switching element SW included in the same memory cell MC1 or MC2, but the present inventive concepts are not limited thereto.

The variable resistance structure VR may be formed of (e.g., may at least partially comprise) a material capable of storing data (e.g., configured to store data). In some example embodiments, the variable resistance structure VR may include a material that is configured to reversibly change phase between a crystalline state and an amorphous state, based on a temperature of the material. For example, the variable resistance structure VR may have (“be associated with”) a first phase transition temperature, which is a threshold temperature associated with a phase transition of a material of the variable resistance structure VR being induced, such that the material changes phase between the crystalline and amorphous states. The first phase transition temperature may be in a range of about 250° C. to 350° C. For example, the variable resistance structure VR may include a compound in which at least one of Te and Se (chalcogen elements) is combined with at least one of Ge, Sb, Bi, Pb, Sn, Ag, As, S, Si, In, Ti, Ga, P, O, and C. For example, the variable resistance structure VR may include at least one of GeSbTe, GeTeAs, SbTeSe, GeTe, SbTe, SeTeSn, GeTeSe, SbSeBi, GeBiTe, GeTeTi, InSe, GaTeSe, and InSbTe. In another example, the variable resistance structure VR may include a superlattice structure in which a Ge-containing layer (e.g., GeTe layer) and a Ge-free layer (e.g., SbTe layer) are repeatedly stacked.

In some example embodiments, the variable resistance structure VR may include at least one of a perovskite compound and a conductive metal oxide. For example, the variable resistance structure VR may include at least one of niobium oxide, titanium oxide, nickel oxide, zirconium oxide, vanadium oxide, PCMO((Pr,Ca)MnO₃), strontium-titanium oxide, barium-strontium-titanium oxide, strontium-zirconium oxide, barium-zirconium oxide, and barium-strontium-zirconium oxide. In another example, the variable resistance structure VR may be either a structure including a conductive metal oxide layer and a tunnel insulation layer, or a structure including a first conductive metal oxide layer, a tunnel insulation layer, and a second conductive metal oxide layer. In this case, the tunnel insulation layer may include aluminum oxide, hafnium oxide, or silicon oxide.

The switching element SW may be a device configured to switch phases based on a threshold switching phenomenon exhibiting a nonlinear I-V curve (e.g., S-type I-V curve). For example, the switching element SW may be an OTS device (e.g., an “Ovonic Threshold Switch device”). The switching element SW may be associated with a second phase transition temperature between a crystalline state and an amorphous state that is greater than the first phase transition temperature associated with the variable resistance structure VR. For example, the switching element SW may have a phase transition temperature that is in a range of about 350° C. to about 450° C. Therefore, when operating a variable resistance memory device according to some example embodiments of the present inventive concepts, the variable resistance structure VR may be configured to reversibly change phase between its crystalline and amorphous states, while the switching element SW may be configured to maintain its substantially amorphous state without the phase transition. In this description, the substantially amorphous state may not exclude the presence of a locally crystalline grain or a locally crystalline portion in an object (e.g., the switching element SW).

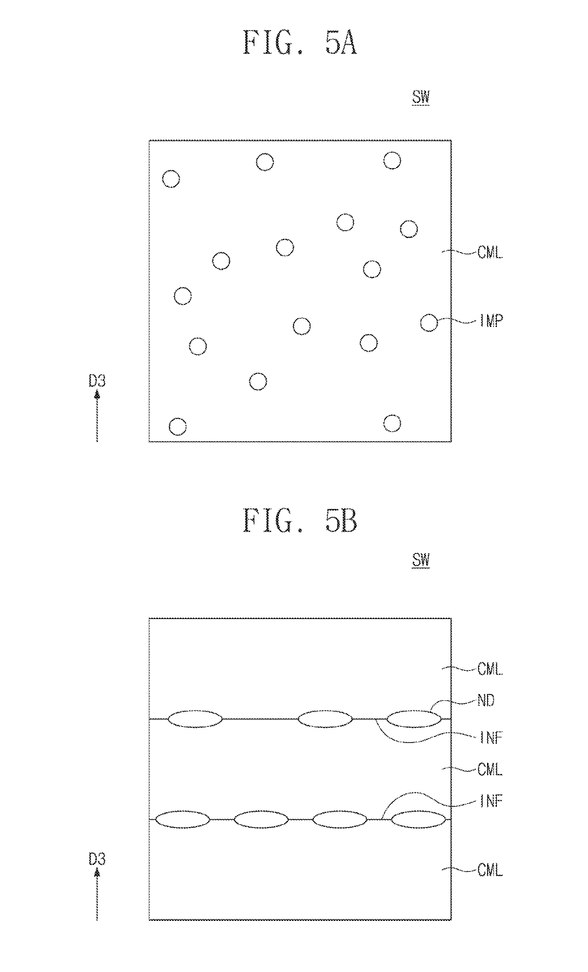

FIGS. 5A and 5B are schematic diagrams illustrating a switching element according to some example embodiments of the present inventive concepts.

Referring further to FIGS. 5A and 5B, the switching element SW may include one or more insulative impurities and a chalcogenide material. In some example embodiments, the switching element SW may further include additional impurities. For example, the additional impurities may be at least one of C, N and B.

The chalcogenide material may include a compound in which at least one of Te and Se (chalcogen elements) is combined with at least one of Ge, Sb, Bi, Al, Pb, Sn, Ag, As, S, Si, In, Ti, Ga and P. For example, the chalcogenide material may include at least one of AsTe, AsSe, GeTe, SnTe, GeSe, SnTe, SnSe, ZnTe, AsTeSe, AsTeGe, AsSeGe, AsTeGeSe, AsSeGeSi, AsTeGeSi, AsTeGeS, AsTeGeSiln, AsTeGeSiP, AsTeGeSiSbS, AsTeGeSiSbP, AsTeGeSeSb, AsTeGeSeSi, SeTeGeSi, GeSbTeSe, GeBiTeSe, GeAsSbSe, GeAsBiTe, and GeAsBiSe.

The insulative impurities may include oxide and/or nitride. In some example embodiments, the insulative impurities may include oxide and/or nitride of at least one of Si, Hf, Zr, W, V, Nb, Ti, Ta, Mo, and Mg. For example, the insulative impurities may include at least one of silicon oxide, hafnium oxide, zirconium oxide, tungsten oxide, vanadium oxide, niobium oxide, titanium oxide, tantalum oxide, molybdenum oxide, magnesium oxide, silicon nitride, hafnium nitride, zirconium nitride, tungsten nitride, vanadium nitride, niobium nitride, titanium nitride, tantalum nitride, molybdenum nitride, and magnesium nitride. In some example embodiments, the insulative impurities may include at least one of oxides and nitrides of elements included in the chalcogenide material. In an example, in case that the chalcogenide material includes Si, the insulative impurities may include at least one of silicon oxide and silicon nitride. In another example, in case that the chalcogenide material includes Ge, the insulative impurities may include at least one of germanium oxide and germanium nitride. In another example, in case that the chalcogenide material includes As, the insulative impurities may include at least one of arsenic oxide and arsenic nitride.

In some example embodiments, as shown in FIG. 5A, the switching element SW may include a chalcogenide material layer CML and the insulative impurities IMP may be dispersed in the chalcogenide material layer CML. In other words, the chalcogenide material layer CML may be doped with the insulative impurities IMP. The chalcogenide material layer CML may include the chalcogenide material mentioned above.

In some example embodiments, as shown in FIG. 5B, the switching element SW may include a plurality of sequentially stacked chalcogenide material layers CML (e.g., a stack of two or more chalcogenide material layers CML). A plurality of insulative nano-islands ND may be provided at interfaces INF between the chalcogenide material layers CML. The insulative nano-island ND may be a region or body in which the insulative impurities are agglomerated. The insulative nano-island ND may have a size of, for example, about 1 nm to about 20 nm. Each of the chalcogenide material layers CML may include the chalcogenide material mentioned above. Each of the chalcogenide material layers CML may have a thickness of, for example, about 1 nm to about 5 nm. FIG. 5B shows that three chalcogenide material layers CML are stacked, but the present inventive concepts are not limited thereto. For example, two chalcogenide material layers CML may be stacked or more than three chalcogenide material layers CML may be stacked.

Each of the memory cells MC1 and MC2 may further include a middle electrode MEL provided between the variable resistance structure VR and the switching element SW. The middle electrode MEL may electrically couple the variable resistance structure VR and the switching element SW to each other, and may prevent a direct contact between the variable resistance structure VR and the switching element SW. The middle electrode MEL may include at least one of W, Ti, Al, Cu, C, CN, TiN, TiAlN, TiSiN, TiCN, WN, CoSiN, WSiN, TaN, TaCN, and TaSiN.

Referring back to FIGS. 4A and 4B, each of the memory cells MC1 and MC2 may further include a first electrode EL1 provided between the variable resistance structure VR and the conductive line CL1 or CL2 coupled thereto. For example, in each of the memory cells MC1 and MC2, the first electrode EL1 may be disposed oppositely to the middle electrode MEL across the variable resistance structure VR. The first electrodes EL1 included in the same memory cell stack MCA1 or MCA2 may be disposed at intersections between the conductive lines CL1, CL2 and CL3, thereby providing a two-dimensional arrangement. The first electrode EL1 may be a heater electrode that heats the variable resistance structure VR to change the phase state of the variable resistance structure VR. The first electrode EL1 may be formed of (e.g., at least partially comprise) a material whose resistivity is greater those of the conductive lines CL1, CL2 and CL3. For example, the first electrode EL1 may include at least one of W, Ti, Al, Cu, C, CN, TiN, TiAlN, TiSiN, TiCN, WN, CoSiN, WSiN, TaN, TaCN, TaSiN, and TiO.

Each of the memory cells MC1 and MC2 may further include a second electrode EL2 provided between the switching element SW and the conductive line CL2 or CL3 coupled thereto. For example, in each of the memory cells MC1 and MC2, the second electrode EL2 may be disposed oppositely to the middle electrode MEL across the switching element SW. As shown in FIGS. 4A and 4B, the second electrodes EL2 included in the same memory cell stack MCA1 or MCA2 may be disposed at intersections between the conductive lines CL1, CL2 and C3, thereby providing a two-dimensional arrangement. However, the present inventive concepts are not limited thereto. In some example embodiments, each of the second electrodes EL2 included in the same memory cell stack MCA1 or MCA2 may extend in either the first direction D1 or the second direction D2 along the conductive line CL2 or CL3 connected thereto. In this case, a single second electrode EL2 may be shared between a plurality of memory cells MC1 or MC2 that are arranged along either the first direction D1 or the second direction D2.

A first interlayer dielectric layer 110 may be provided on the substrate 100. The first interlayer dielectric layer 110 may cover the first conductive lines CL1 and further cover the first electrodes EL1, the variable resistance structures VR, and the middle electrodes MEL that are included in the first memory cells MC1.

A second interlayer dielectric layer 120 may be provided on the first interlayer dielectric layer 110. The second interlayer dielectric layer 120 may cover the switching elements SW and the second electrodes EL2 that are included in the first memory cells MC1.

A third interlayer dielectric layer 130 may be provided on the second interlayer dielectric layer 120. The third interlayer dielectric layer 130 may cover the second conductive lines CL2 and further cover the first electrodes EL1, the variable resistance structures VR, and the middle electrodes MEL that are included in the second memory cells MC2.

A fourth interlayer dielectric layer 140 may be provided on the third interlayer dielectric layer 130. The fourth interlayer dielectric layer 140 may cover the switching elements SW and the second electrodes EL2 that are included in the second memory cells MC2.

The first interlayer dielectric layers 110 to fourth interlayer dielectric layers 140 may include at least one of silicon oxide, silicon nitride, and silicon oxynitride.

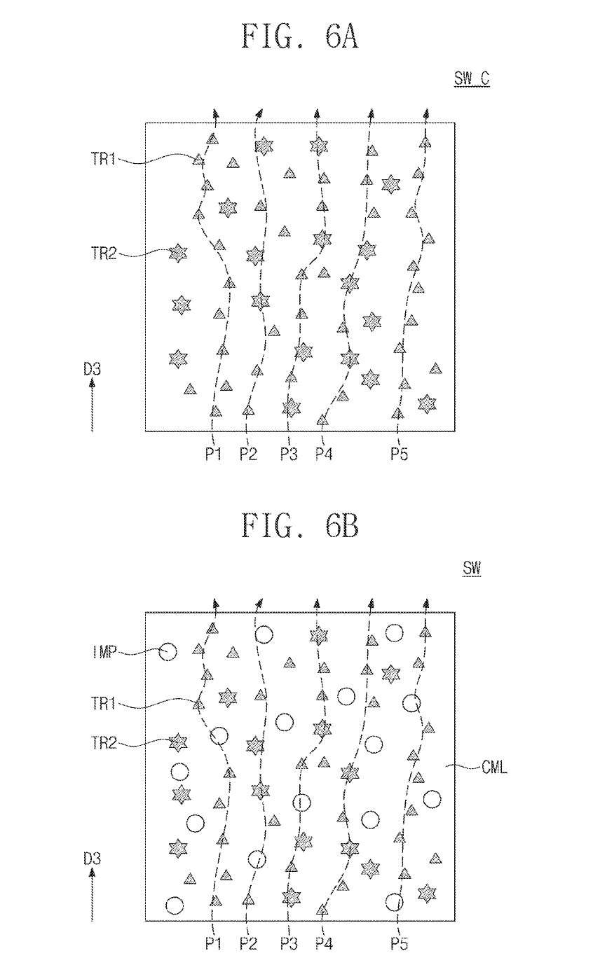

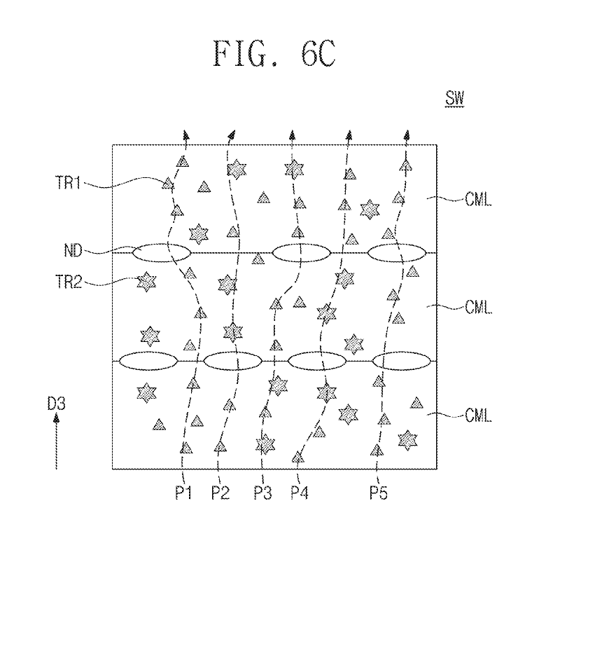

FIG. 6A is a schematic diagram illustrating a current flow in a switching element without insulative impurities. Each of FIGS. 6B and 6C is a schematic diagram illustrating a current flow in a switching element according to some example embodiments of the present inventive concepts. For example, FIG. 6B shows a current flow in the switching element discussed with reference to FIG. 5A, and FIG. 6C shows a current flow in the switching element discussed with reference to FIG. 5B.

A chalcogenide material may include intrinsic traps having different binding energies, respectively. In this description, the binding energy of a trap (e.g., an intrinsic trap) may mean a minimum energy required for an electron to escape from the trap in which the electron is trapped. When a voltage is applied to the chalcogenide material, an electron may move within the chalcogenide material by repeatedly being bound to and escaping from adjacent traps along a voltage-applied direction. In other words, when a voltage is applied to the chalcogenide material, an electron may move within the chalcogenide material by hopping between traps adjacently arranged along the voltage-applied direction.

Referring to FIG. 6A, a switching element SW_C may include a chalcogenide material. The switching element SW_C may thus include intrinsic traps TR1 and TR2 having binding energies different from each other. For example, the switching element SW_C may include first intrinsic traps TR1 having a first binding energy and second intrinsic traps TR2 having a second binding energy that is greater than the first binding energy.

When the switching element SW_C is supplied with a voltage in the third direction D3, electrons may move within the switching element SW_C by hopping between traps adjacently arranged along the third direction D3. For example, electrons may move along first to fifth paths P1 to P5.

In this case, some paths may consist solely of intrinsic traps having a relatively lower binding energy. These paths may serve as a movement path along which electrons move even under a relatively lower voltage, which may cause leakage current. For example, the first and fifth paths P1 and P5 may consist solely of first intrinsic traps TR1 and thus may cause leakage current.

Referring to FIG. 6B, the switching element SW may include insulative impurities IMP and a chalcogenide material. In some example embodiments, including the example embodiments illustrated in FIG. 6B, the chalcogenide material layer CML may be doped with the insulative impurities IMP. The insulative impurities IMP may serve as traps whose binding energies are greater than those of intrinsic traps (e.g., the first intrinsic traps TR1) having a binding energy relatively lower than those of other intrinsic traps (e.g., the second intrinsic traps TR2) included in the chalcogenide material. For example, the binding energy of the insulative impurities IMP may be greater than those of the first intrinsic traps TR1.

The insulative impurities IMP may be additionally incorporated to the paths P1 to P5 at least partially comprising the intrinsic traps TR1 and TR2 included in the chalcogenide material. It therefore may be possible to reduce paths consisting solely of intrinsic traps having a relatively lower binding energy. For example, the first to fifth paths P1 to P5 may include the insulative impurities IMP.

Referring to FIG. 6C, the switching element SW may include insulative impurities and a chalcogenide material. In some example embodiments, including the example embodiments illustrated in FIG. 6C, the insulative impurities may be provided as the insulative nano-islands ND at the interfaces INF between the chalcogenide material layers CML. The insulative nano-islands ND at least partially comprising the insulative impurities may serve as traps whose binding energies are greater than those of intrinsic traps (e.g., the first intrinsic traps TR1) having a binding energy relatively lower than those of other intrinsic traps (e.g., the second intrinsic traps TR2) included in the chalcogenide material. For example, the binding energy of the insulative nano-island ND may be greater than those of the first intrinsic traps TR1.

The insulative nano-islands ND may be additionally incorporated to the paths P1 to P5 at least partially comprising the intrinsic traps TR1 and TR2 of the chalcogenide material. It therefore may be possible to reduce paths consisting solely of intrinsic traps having a relatively lower binding energy. For example, the first to fifth paths P1 to P5 may include the insulative nano-island NDs.

In conclusion, according to some example embodiments of the present inventive concepts, it may be possible to reduce paths consisting solely of intrinsic traps having a relatively lower binding energy and thus leakage current may decrease.

The aforementioned description is based on the current understanding on the operation of an OTS device. It therefore will be apparent to one skilled in the art that a theoretical description about the device is based on the current understanding on the operation of an OTS device. However, it should be understood that devices and methods set forth herein are not limited to the aforementioned theoretical description.

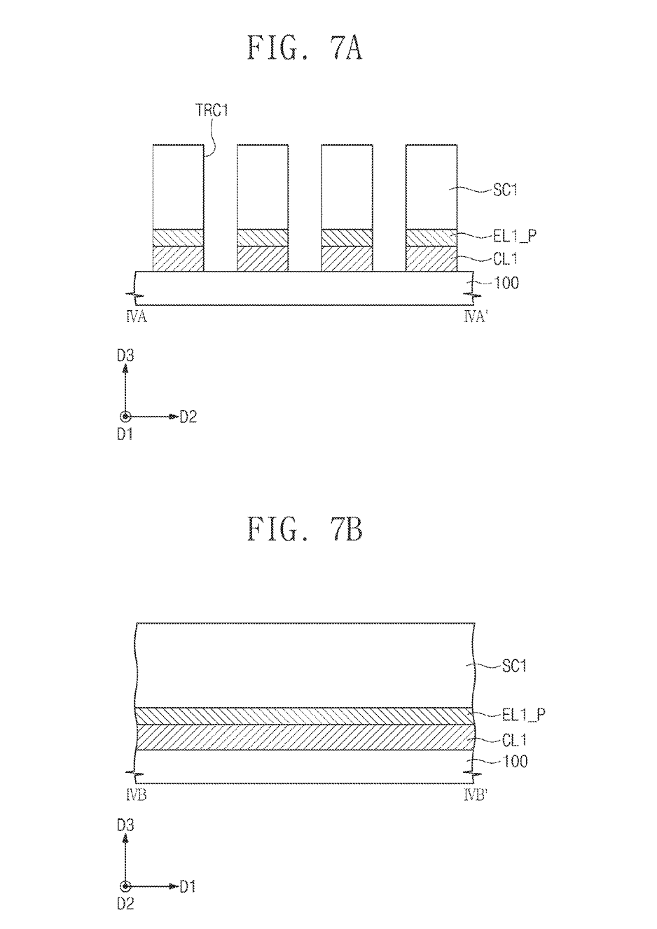

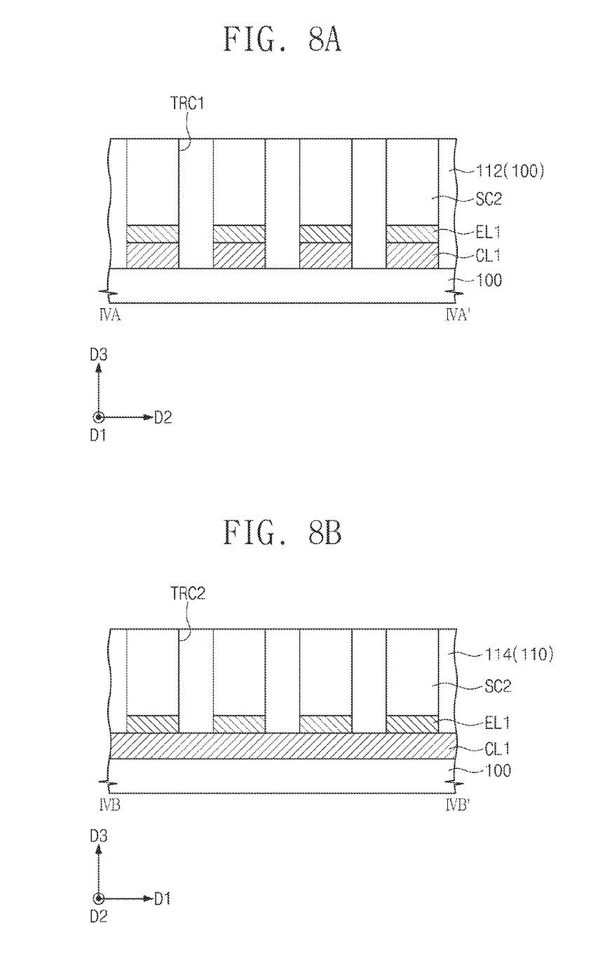

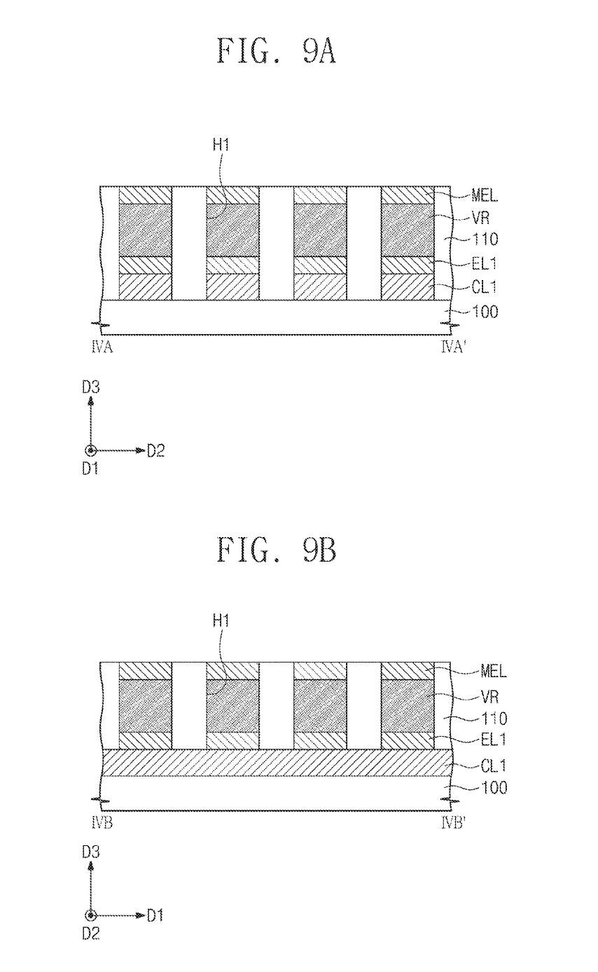

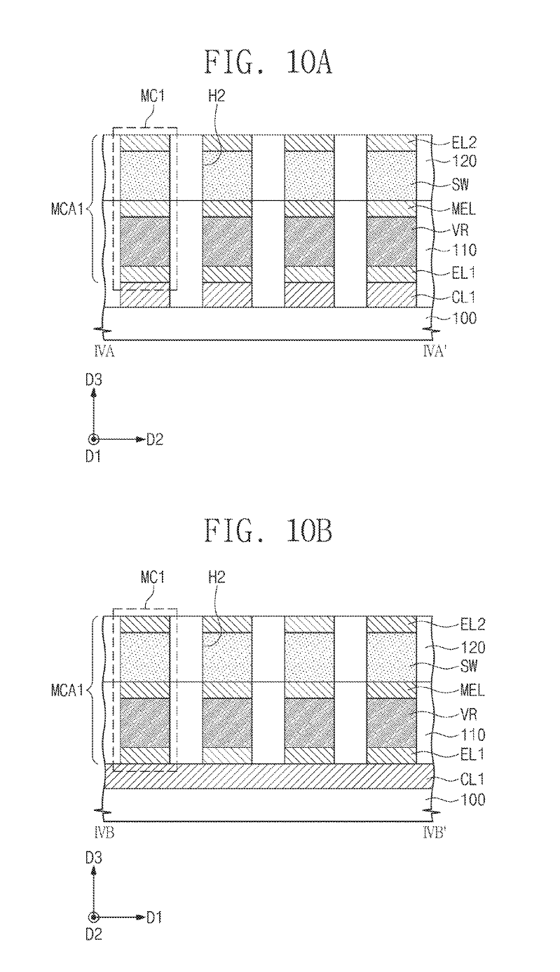

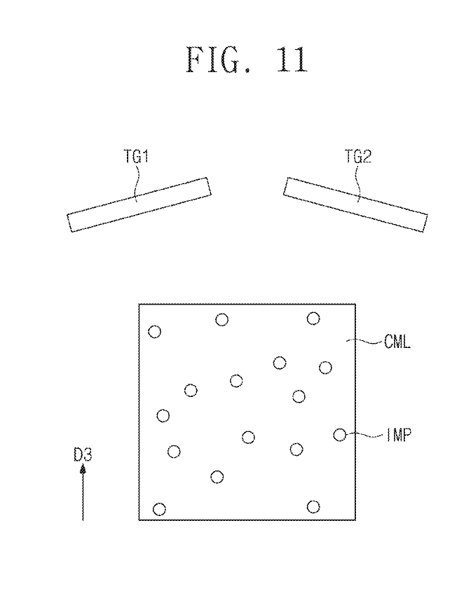

FIGS. 7A to 10A are cross-sectional views corresponding line IVA-IVA′ of FIG. 3 for explaining a method of fabricating a variable resistance memory device according to some example embodiments of the present inventive concepts. FIGS. 7B to 10B are cross-sectional views corresponding line IVB-IVB′ of FIG. 3 for explaining a method of fabricating a variable resistance memory device according to some example embodiments of the present inventive concepts. Components substantially same as those discussed with reference to FIGS. 3, 4A, 4B, 5A and 5B are allocated the same reference numerals, and repetitive description may be omitted in the interest of brevity.

Referring to FIGS. 7A and 7B, first conductive lines CL1, preliminary first electrodes EL1_P, and first sacrificial patterns SC1 may be sequentially formed on a substrate 100. Ones of the first conductive lines CL1, the preliminary first electrodes EL1_P, and the first sacrificial patterns SC1 may extend in a first direction D1, and may be spaced apart from each other in a second direction D2 intersecting the first direction by first trenches TRC1 extending in the first direction D1. The formation of the first conductive lines CL1 and the preliminary electrodes EL1_P may include, for example, depositing a first conductive layer (not shown) and a first electrode layer (not shown) on the substrate 100, forming the first sacrificial patterns SC1 on the first electrode layer, and sequentially etching the first conductive layer and the first electrode layer using the first sacrificial patterns SC1 as an etching mask. The first sacrificial patterns SC1 may include a material having an etch selectivity with respect to first and second filling insulation layers that are discussed below.

Referring to FIGS. 8A and 8B, a first filling insulation layer 112 may be formed to fill the first trenches TRC1. The formation of the first filling insulation layer 112 may include forming an insulation layer (not shown) to fill the first trenches TRC1 and performing a planarization process until the first sacrificial patterns SC1 are exposed. The first filling insulation layer 112 may include at least one of silicon oxide, silicon nitride, and silicon oxynitride.

The first sacrificial patterns SC1 and the preliminary first electrodes EL1_P may be sequentially patterned to form second sacrificial patterns SC2 and first electrodes EL1, respectively. The second sacrificial patterns SC2 are separated from each other in the first direction D1 and the first electrodes EL1 are separated from each other in the first direction D1. The patterning process may include forming mask patterns (not shown) extending in the second direction D2 on the first filling insulation layer 112 and the first sacrificial patterns SC1, and sequentially etching the first sacrificial patterns SC1 and the preliminary first electrodes EL1_P using the mask patterns as an etching mask. The patterning process may form second trenches TRC2 extending in the second direction D2. The second trench TRC2 may include a bottom surface whose level is the same as or higher than that of a top surface of the first conductive line CL1. In other words, the first conductive lines CL1 may not be patterned by the patterning process.

A second filling insulation layer 114 may be formed to fill the second trenches TRC2. The formation of the second filling insulation layer 114 may include forming an insulation layer (not shown) to fill the second trenches TRC12 and performing a planarization process until the second sacrificial patterns SC2 are exposed. The second filling insulation layer 114 may include at least one of silicon oxide, silicon nitride, and silicon oxynitride. A first interlayer dielectric layer 110 may be defined to include the first filling insulation layer 112 and the second filling insulation layer 114.

Referring to FIGS. 9A and 9B, the second sacrificial patterns SC2 may be selectively removed to form first holes H1 separated in the first and second directions D1 and D2. For example, in case that the first interlayer dielectric layer 110 includes a silicon nitride and/or a silicon oxynitride and the second sacrificial patterns SC2 includes a silicon oxide, an etchant including phosphoric acid may be used to selectively remove the second sacrificial patterns SC2. The first holes H1 may expose top surfaces of the first electrodes EL1.

Variable resistance structures VR may be formed on the first electrodes EL1 exposed through the first holes H1. The variable resistance structures VR may not completely fill the first holes H1. For example, the formation of the variable resistance structures VR may include forming a variable resistance layer (not shown) to completely fill the first holes H1 and performing an etch back process on the variable resistance layer. The variable resistance structure VR may include a material the same as that discussed with reference to FIGS. 3, 4A and 4B.

Middle electrodes MEL may be formed on the variable resistance structures VR, so that the first holes H1 may be filled. The formation of the middle electrodes MEL may include depositing a middle electrode layer to fill the first holes H1 and performing a planarization process until exposing the first interlayer dielectric layer 110.

Referring to FIGS. 10A and 10B, a second interlayer dielectric layer 120 may be formed on the first interlayer dielectric layer 110. The second interlayer dielectric layer 120 may include second holes H2 through which the middle electrodes MEL are exposed.

Switching elements SW may be formed on the middle electrodes MEL exposed through the second holes H2. The switching elements SW may not completely fill the second holes H2. For example, the formation of the switching elements SW may include forming a switching layer (not shown) to completely fill the second holes H2 and performing an etch back process on the switching layer.

The switching elements SW may include insulative impurities and a chalcogenide material. In some example embodiments, the switching element SW may further include additional impurities. For example, the additional impurities may be at least one of C, N and B. The chalcogenide material may include a compound in which at least one of Te and Se (chalcogenide elements) is combined with at least one of Ge, Sb, Bi, Al, Pb, Sn, Ag, As, S, Si, In, Ti, Ga and P. For example, the chalcogenide material may include at least one of AsTe, AsSe, GeTe, SnTe, GeSe, SnTe, SnSe, ZnTe, AsTeSe, AsTeGe, AsSeGe, AsTeGeSe, AsSeGeSi, AsTeGeSi, AsTeGeS, AsTeGeSiln, AsTeGeSiP, AsTeGeSiSbS, AsTeGeSiSbP, AsTeGeSeSb, AsTeGeSeSi, SeTeGeSi, GeSbTeSe, GeBiTeSe, GeAsSbSe, GeAsBiTe, and GeAsBiSe.

FIG. 11 shows a method of fabricating a switching element according to some example embodiments of the present inventive concepts. In detail, FIG. 11 shows a method of fabricating the switching element discussed with reference to FIG. 5A.

Referring to FIG. 11, a co-sputtering process may be used to form the switching elements SW. The co-sputtering process may be achieved by performing a sputtering process simultaneously using a first target material TG1 and a second target material TG2. The first target material TG1 may include the chalcogenide material, and the second target material TG2 may include an insulative impurity material. The insulative impurity material may include oxide and/or nitride. In some example embodiments, the insulative impurity material may include oxide and/or nitride of at least one selected from Si, Hf, Zr, W, V, Nb, Ti, Ta, Mo, and Mg. In some example embodiments, the insulative impurity material may include at least one of oxides and nitrides of elements included in the chalcogenide material. A chalcogenide material layer CML may be formed from the first target material TG1, and insulative impurities IMP may be formed from the second target material TG2. The insulative impurities IMP may be dispersed in the chalcogenide material layer CML

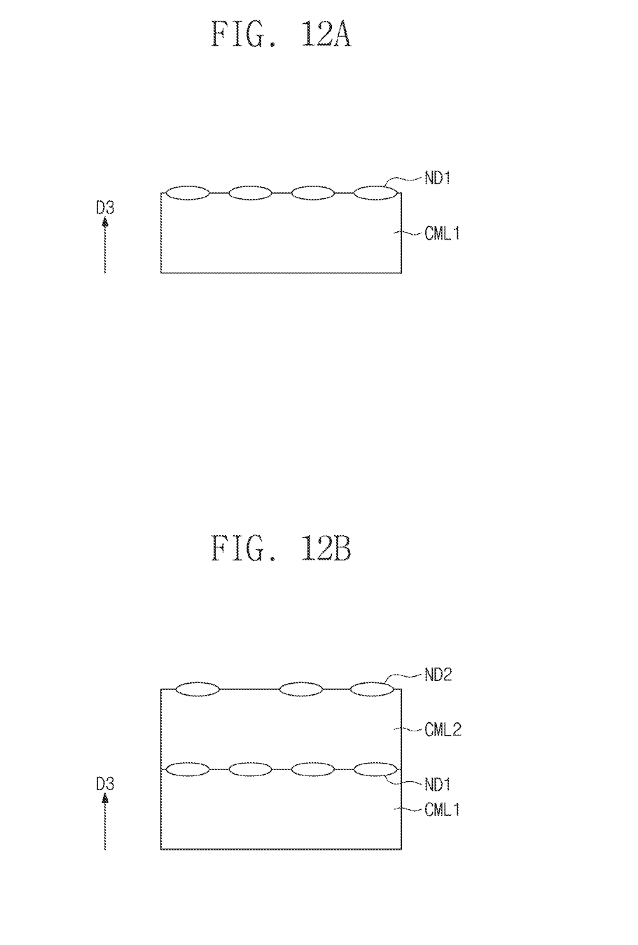

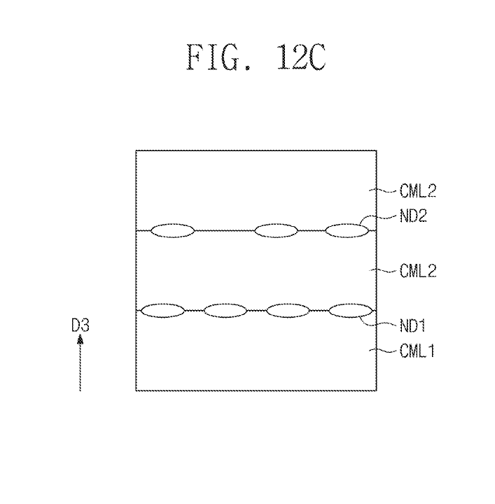

FIGS. 12A to 12C show a method of fabricating a switching element according to some example embodiments of the present inventive concepts. In detail, FIGS. 12A to 12C show a method of fabricating the switching element discussed with reference to FIG. 5B.

Referring to FIG. 12A, a first chalcogenide material layer CML1 may be formed. The first chalcogenide material layer CML1 may include the chalcogenide material. The first chalcogenide material layer CML1 may have a thickness of about 1 nm to about 5 nm. For example, a sputtering process may be performed to form the first chalcogenide material layer CML1.

First insulative nano-islands ND1 may be formed on a top surface of the first chalcogenide material layer CML1.

For example, the first insulative nano-islands ND1 may be formed by heating the first chalcogenide material layer CML1 or irradiating laser on the top surface (e.g., “upper surface”) of the first chalcogenide material layer CML1 under an oxygen and/or nitrogen atmosphere (e.g., “in an oxygen and/or nitrogen atmosphere”). In this case, the first insulative nano-island ND1 may include at least one of oxides and nitrides of elements included in the chalcogenide material.

Alternatively, the first insulative nano-islands ND1 may be formed by depositing an insulative impurity material on the top surface of the first chalcogenide material layer CML1. The insulative impurity material may include oxide and/or nitride of at least one selected from Si, Hf, Zr, W, V, Nb, Ti, Ta, Mo, and Mg. Alternatively, the insulative impurity material may include at least one of oxides and nitrides of elements included in the chalcogenide material.

Referring to FIG. 12B, a second chalcogenide material layer CML2 may be formed on the first chalcogenide material layer CML1. Thereafter, second insulative nano-islands ND2 may be formed on a top surface of the second chalcogenide material layer CML2. The formation of the second chalcogenide material layer CML2 and the second insulative nano-islands ND2 may be substantially the same as the formation of the first chalcogenide material layer CML1 and the first insulative nano-island ND1, respectively, discussed above.

Referring to FIG. 12C, a third chalcogenide material layer CML3 may be formed on the second chalcogenide material layer CML2. The formation of the third chalcogenide material layer CML3 may be substantially the same as the formation of the first chalcogenide material layer CML1 discussed above.

With reference to FIGS. 12A to 12C, discussed are the formation of the sequentially stacked three chalcogenide material layers CML1, CML2 and CML3 and the formation of the insulative nano-islands ND1 and ND2 positioned between the chalcogenide material layers CML1 to CLM3, but the present inventive concepts is not limited thereto. For example, two chalcogenide material layers may be formed or more than three chalcogenide material layers may be formed.

Referring back to FIGS. 10A and 10B, second electrodes EL2 filing the second holes H2 may be formed on the switching elements SW. The formation of the second electrodes EL2 may include depositing a second electrode layer (not shown) to fill the second holes H2 and performing a planarization process until the second interlayer dielectric layer 120 is exposed.

A first memory cell stack MCA1 may be obtained through the formation of the second electrodes EL2. The first memory cell stack MCA1 may include first memory cells MC1 that are two-dimensionally arranged on the first conductive lines CL1. Each of the first memory cells MC1 may include the variable resistance structure VR and the switching element SW.

Each of the first memory cells MC1 fabricated by the aforementioned processes may include the first electrode EL1, the variable resistance structure VR, the middle electrode MEL, the switching element SW, and the second electrode EL2 that are sequentially stacked. However, the present inventive concepts are not limited to the processes described above. For example, the process for forming the variable resistance structure VR may be interchangeable with the process for forming the switching element SW, and the process for forming the first electrode EL1 may also be interchangeable with the process for forming the second electrode EL2. Each of the first memory cells fabricated by the interchanged processes MC1 may include the second electrode EL2, the switching element SW, the middle electrode MEL, the variable resistance structure VR, and the first electrode EL1 that are sequentially stacked.

Referring back to FIGS. 4A and 4B, second conductive lines CL2 and second memory cell stack MCA2 may be formed on the first memory cell stack MCA1. The second memory cell stack MCA2 may include arranged two-dimensionally. The formation of the second conductive lines CL2 and the second memory cell stack MCA2 may be substantially the same as the formation of the first conductive lines CL1 and the first memory cell stack MCA1, respectively. However, the second conductive lines CL2 may be formed to extend in the second direction D2 different from the first conductive lines CL1.

Third conductive lines CL3 may be formed, on the second memory cell stack MCA2, to extend in the first direction D1. Each of the third conductive lines CL3 may be electrically coupled to the second memory cells MC2 arranged along the first direction D1.

In case that more than three memory cell stacks are included in a variable resistance memory device according to some example embodiments of the present inventive concepts, additional processes which are substantially same with the processes to form the first and second memory cell stacks MCA1 and MCA2 and the second and third conductive lines CL2 and CL3 may be repeatedly performed.

According to some example embodiments of the present inventive concepts, the switching element may include the insulative impurities and the chalcogenide material. The insulative impurities may serve as traps whose binding energies are greater than those of intrinsic traps having a binding energy relatively lower than those of other intrinsic traps included in the chalcogenide material. The insulative impurities may be incorporated to paths at least partially comprising intrinsic traps included in the chalcogenide material. It therefore may be possible to reduce paths consisting solely of intrinsic traps having a relatively lower binding energy. In conclusion, leakage current of the switching element may decrease and reliability of the variable resistance memory device may arise.

Although the present inventive concepts have been described in connection with the embodiments of the present inventive concepts illustrated in the accompanying drawings, it is not limited thereto. The above-disclosed embodiments shout thus be considered illustrative and not restrictive.

What is claimed is:

1. A device, comprising:
a memory cell configured to be electrically coupled to separate conductive lines at opposite ends, the memory cell including,
a switching element including at least one insulative impurity and a chalcogenide material, and
a variable resistance structure coupled to the switching element, such that the switching element and the variable resistance structure are coupled in series between the opposite ends of the memory cell.

2. The device of claim 1, wherein the switching element includes,
a stack of two or more chalcogenide material layers; and
at least one insulative nano-island at each interface between adjacent chalcogenide material layers in the stack of two or more chalcogenide material layers, each insulative nano-island including the at least one insulative impurity.

3. The device of claim 2, wherein each chalcogenide material layer has a thickness of about 1 nm to about 5 nm.

4. The device of claim 1, wherein the switching element includes a chalcogenide material layer, the chalcogenide material layer being doped with the at least one insulative impurity.

5. The device of claim 1, wherein the at least one insulative impurity includes oxide and/or nitride of at least one of Si, Hf, Zr, W, V, Nb, Ti, Ta, Mo, and Mg.

6. The device of claim 1, wherein the at least one insulative impurity includes at least one of oxides and nitrides of elements included in the chalcogenide material.

7. The device of claim 1, wherein the chalcogenide material includes,
at least one of Te and Se, and
at least one of Ge, Sb, Bi, Al, Pb, Sn, Ag, As, Si, In, Ti, Ga, and P.

8. A method of fabricating a variable resistance memory device, the method comprising:
forming a first conductive line extending on a substrate, the first conductive line extending in a first direction;
forming a memory cell on the first conductive line, forming the memory cell including forming a switching element and a variable resistance structure coupled in series, the switching element including at least one insulative impurity and a chalcogenide material; and
forming a second conductive line on the memory cell and extending in a second direction that intersects the first direction, such that the memory cell is electrically coupled to both the first conductive line and the second conductive line.

9. The method of claim 8, wherein forming the switching element includes simultaneously depositing the at least one insulative impurity and the chalcogenide material according to a co-sputtering process.

10. The method of claim 8, wherein forming the switching element includes,
forming a first chalcogenide material layer;
forming the at least one insulative impurity on an upper surface of the first chalcogenide material layer; and
forming a second chalcogenide material layer on the first chalcogenide material layer.

11. The method of claim 10, wherein forming the at least one insulative impurity includes heating the first chalcogenide material layer in an oxygen and/or nitrogen atmosphere.

12. The method of claim 10, wherein forming the at least one insulative impurity includes irradiating the upper surface of the first chalcogenide material layer in an oxygen and/or nitrogen atmosphere.

13. The method of claim 10, wherein forming the at least one insulative impurity includes depositing the at least one insulative impurity on the upper surface of the first chalcogenide material layer.

14. The method of claim 8, wherein the at least one insulative impurity includes at least one of an oxide and a nitride of at least one of Si, Hf, Zr, W, V, Nb, Ti, Ta, Mo, and Mg.

15. The method of claim 8, wherein the at least one insulative impurity includes at least one of an oxide and a nitride of at least one compound included in the chalcogenide material.

16. A device, comprising:
a memory cell configured to be electrically coupled to separate conductive lines at opposite ends, the memory cell including,
a variable resistance structure configured to reversibly switch phases, between a crystalline state and an amorphous state, at a first phase transition temperature, and
a switching element configured to reversibly switch phases, between a crystalline state and an amorphous state, at a second phase transition temperature,
wherein the second phase transition temperature is greater than the first phase transition temperature, and
wherein the switching element includes at least one insulative impurity and a chalcogenide material.

17. The device of claim 16, wherein,
the first phase transition temperature is in a range of about 250° C. to 350° C.; and
the second phase transition temperature is in a range of about 350° C. to about 450° C.

18. The device of claim 16, wherein the switching element is an ovonic threshold switch device.

19. The device of claim 16, wherein the switching element includes,
a stack of two or more chalcogenide material layers; and
at least one insulative nano-island at each interface between adjacent chalcogenide material layers in the stack of two or more chalcogenide material layers, each insulative nano-island including the at least one insulative impurity.

20. The device of claim 16, wherein the switching element includes a chalcogenide material layer, the chalcogenide material layer being doped with the at least one insulative impurity.
